(19) United States
(12) Patent Application Publication
(10) Pub. No.: US 2012/0070960 A1
(43) Pub. Date: Mar. 22, 2012

(54) DICING DIE BOND FILM, METHOD OF MANUFACTURING DICING DIE BOND FILM, AND METHOD OF MANUFACTURING SEMICONDUCTOR DEVICE

(76) Inventors: Shuhei MURATA, Ibaraki-shi (JP); Takeshi MATSUMURA, Ibaraki-shi (JP); Yuichiro YANAGI, Ibaraki-shi (JP)

(21) Appl. No.: 13/237,548

(22) Filed: Sep. 20, 2011

(30) Foreign Application Priority Data
Sep. 21, 2010 (JP) 2010-211088

(51) Int. Cl. H01L 21/78; B32B 37/02; B32B 37/14; B32B 37/06; B32B 7/12; B32B 37/12

(52) U.S. Cl. 438/464; 428/345; 156/275.5; 257/E21.599

(57) ABSTRACT

The present invention aims to provide a dicing die bond film that is capable of suppressing peeling of the dicing die bond film from a dicing ring. The present invention provides a dicing die bond film in which the pressure-sensitive adhesive layer contains a polymer formed by performing an addition reaction on a specific acrylic polymer with a specific isocyanate compound, and a specific crosslinking agent, and the specific peeling adhesive power of a portion of the pressure-sensitive adhesive layer where the dicing ring is pasted is 1.0 N/20 mm tape width or more and 10.0 N/20 mm tape width or less, the tensile storage modulus at 23° C. of the portion where the dicing ring is pasted is 0.05 MPa or more and less than 0.4 MPa, and the die bond film is pasted to the pressure-sensitive adhesive layer after irradiation with an ultraviolet ray.

### BACKGROUND OF THE INVENTION

1. Field of the Invention

The present invention relates to a dicing die bond film, that is used in dicing of a workpiece (semiconductor wafer, etc.) under the condition where an adhesive for fixing a chip-shaped workpiece (semiconductor chip, etc.) and an electrode member is provided on the workpiece before dicing.

2. Description of the Related Art

A semiconductor wafer (workpiece) in which a circuit pattern is formed is diced into semiconductor chips (chip-shaped workpiece) (a dicing step) after the thickness thereof is adjusted as necessary by backside polishing. In the dicing step, the semiconductor wafer is generally washed with an appropriate liquid pressure (normally, about 2 kg/cm²) in order to remove a cutting layer. The semiconductor chip is then fixed onto an adherend such as a lead frame with an adhesive (amounting step), and then transferred to a bonding step. In the mounting step, the adhesive has been applied onto the lead frame or the semiconductor chip. However, with this method, it is difficult to make the adhesive layer uniform and a special apparatus and a long period of time become necessary in the application of the adhesive. For this reason, a dicing die bond film is proposed that adhesively holds the semiconductor wafer in the dicing step and also imparts an adhesive layer for fixing a chip that is necessary in the mounting step (for example, see Patent Document 1: Japanese Patent Application Laid-Open (JP-A) No. 60-57642).

The dicing die bond film described in Patent Document 1 is composed of an adhesive layer that is formed on a supporting base material so that it can be peeled. That is, the dicing die bond film is made so that after the semiconductor wafer is diced while being held by the adhesive layer, the semiconductor chip is peeled together with the adhesive layer by stretching the supporting base material, the semiconductor chips are individually recovered, and then they are fixed onto an adherend such as a lead frame with the adhesive layer interposed therebetween.

Good holding strength toward the semiconductor wafer so that a dicing failure, a dimensional error, etc. do not occur and good peeling property in which the semiconductor chip after dicing can be peeled from the supporting base material integrally with the adhesive layer are desired for the adhesive layer of this type of the dicing die bond film. However, it has been by no means easy to balance both these characteristics. Particularly, when a large holding strength is required for the adhesive layer such as in the method of dicing the semiconductor wafer with a rotary round blade, it has been difficult to obtain a dicing die bond film that satisfies the above characteristics.

Therefore, in order to overcome such problems, various improvement methods have been proposed (for example, see Patent Document 2: Japanese Patent Application Laid-Open (JP-A) No. hei02-248064). In Patent Document 2, a method of interposing a pressure sensitive adhesive layer that can be cured by ultraviolet rays between the supporting base material and the adhesive layer, decreasing the adhering force between the pressure sensitive adhesive layer and the adhesive layer by curing this with ultraviolet rays after dicing, and facilitating picking up the semiconductor chip by peeling both layers is proposed.

However, there is the case where a dicing die bond film that is excellent in balance between holding strength upon dicing and peeling property after dicing is hardly obtained even by this modified method. For example, when a large semiconductor chip measuring 10 mm×10 mm or more or a very thin semiconductor chip measuring 25 to 75 μm in thickness is to be obtained, it is not easy to pick up the semiconductor chip using a common die bonder.

Conventionally, a dicing die bond film including a dicing film including a base and a pressure-sensitive adhesive layer provided thereon and a die bond film provided on the pressure-sensitive adhesive layer is disclosed, in which a specified polymer is contained in the pressure-sensitive adhesive layer of the dicing film and that is capable of maintaining a holding power during dicing and improving the peeling property during pickup by controlling the added amount of a crosslinking agent (for example, see Patent Document 3: Japanese Patent Application Laid-Open No. 2009-170787).

### SUMMARY OF THE INVENTION

There has been room for improvement of the dicing die bond film according to Japanese Patent Application Laid-Open No. 2009-170787 in that the dicing die bond film may be peeled from a dicing ring when pasting the dicing die bond film to the dicing ring in a case where the pasting conditions such as pasting speed, pressure, and tension of the pasting apparatus are inappropriate, or in the case where it is difficult for the dicing die bond film to be pasted to the dicing ring because the dicing ring is soiled or scratched.

The present invention has been made in view of the above-described problems, and an object thereof is to provide a dicing die bond film that is capable of maintaining its holding power during dicing and improving the peeling property during pickup regardless of the conditions of the pasting apparatus when the dicing die bond film is pasted to the dicing ring, and is capable of keeping the dicing die bond film from peeling from the dicing ring, a method of manufacturing a dicing die bond film, and a method of manufacturing a semiconductor device using the dicing die bond film.

The present invention provides the following aspects to achieve the above-described object. That is, the dicing die bond film according to the present invention is a dicing die bond film including a dicing film including a base and a pressure-sensitive adhesive layer provided thereon, and a die bond film provided on the dicing film, wherein the pressure-sensitive adhesive layer contains a polymer formed by performing an addition reaction on an acrylic polymer containing 10 to 40 mol % of a hydroxyl group-containing monomer with an isocyanate compound having 70 to 90 mol % of a radical reactive carbon-carbon double bond to the hydroxyl group-containing monomer, and a crosslinking agent having two or more functional groups exhibiting reactivity to a hydroxyl group in a molecule and having a content of 0.5 to 2 parts by weight to 100 parts by weight of the polymer, and is cured by ultraviolet ray radiation under a prescribed condition, the 180 degree peeling adhesive power to a silicon mirror wafer of a portion of the pressure-sensitive adhesive layer where a dicing ring is pasted is 1.0 N/20 mm tape width or more and 10.0 N/20 mm tape width or less under conditions of a measurement temperature of 23±3° C. and a tensile speed 300 of mm/min, the tensile storage modulus at 23° C. of a portion where the dicing ring is pasted is 0.05 MPa or more and less than 0.4 MPa, and the die bond film is pasted to the pressure-sensitive adhesive layer after irradiation with an ultraviolet ray.

The pressure-sensitive adhesive layer is formed through curing by ultraviolet irradiation in advance before bonding to the die bond film. Therefore, the surface of the pressure-sensitive adhesive layer is hard, thus making it possible to decrease the degree of adhesion with the die bond film upon bonding. Whereby, the anchor effect between the pressure-sensitive adhesive layer and the die bond film is decreased and, for example, in the case of picking up the semiconductor chip, peeling property between the pressure-sensitive adhesive layer and the die bond film becomes satisfactory. As a result, pickup properties can be improved. When the pressure-sensitive adhesive layer is cured by ultraviolet irradiation, the volume of the pressure-sensitive adhesive layer decreases as a result of formation of a crosslinking structure. Therefore, when the pressure-sensitive adhesive layer is cured by irradiating with ultraviolet rays after bonding with the die bond film, stress is applied to the die bond film. As a result, the entire dicing die bond film may undergo warpage. However, since the dicing die bond film of the present invention is formed by bonding with the die bond film after curing by ultraviolet irradiation, it is possible to prevent unnecessary stress from applying on the die bond film. As a result, a dicing die bond film free from warpage can be obtained.

The pressure-sensitive adhesive layer contains, as an essential component, a crosslinking agent having two or more functional groups in the molecule, which exhibit reactivity with a hydroxyl group, and the tensile elastic modulus is adjusted by controlling the additive amount of the crosslinking agent so as to achieve satisfactory pickup properties while maintaining holding strength upon dicing. Because the content of the crosslinking agent of the present invention is 2 parts by weight or less to 100 parts by weight of the polymer, the crosslinking of the polymer is suppressed, the tensile storage modulus is decreased, and high adhesive power of the dicing ring pasting portion can be maintained. As a result, the dicing die bond film can be suppressed from peeling from the dicing ring when dicing a semiconductor wafer. On the other hand, because the content is 0.5 parts by weight or more, the pressure-sensitive adhesive has sufficient cohesive strength, and generation of adhesive residue can be prevented when the dicing film is peeled from the dicing ring after pickup.

Furthermore, poor crosslinking after ultraviolet irradiation is suppressed by adjusting the content of the hydroxyl group-containing monomer to 10 mol % or more. As a result, it is possible to prevent deterioration of pickup properties. In contrast, by adjusting the content to 40 mol % or less, it is possible to prevent deterioration of pickup properties caused by the fact that the polarity of the pressure-sensitive adhesive becomes high and the interaction with the die bond film becomes intense, which makes it difficult to perform satisfactory peeling. Decrease in productivity due to partial gelatinization of the polymer can be also prevented.

Furthermore, in the present invention, the addition reaction is performed on an acrylic polymer containing 10 to 40 mol % of a hydroxyl group-containing monomer with an isocyanate compound having a radical reactive carbon-carbon double bond, and the pressure-sensitive adhesive is cured by ultraviolet ray irradiation before pasting the die bond film. Therefore, even when crosslinking by the crosslinking agent is suppressed, the pressure-sensitive adhesive is sufficiently cured by the ultraviolet ray irradiation, and a good pickup property can be obtained.

Because the tensile storage modulus at 23° C. of a portion of the pressure-sensitive adhesive layer where the dicing ring is pasted is 0.05 MPa or more and less than 0.4 MPa, high adhesive power can be maintained, and the dicing die bond film can be kept from peeling from the dicing ring during dicing of the semiconductor wafer. On the other hand, because the tensile storage modulus is 0.05 MPa or more, generation of adhesive residue can be prevented when the dicing film is peeled from the dicing ring.

The 180 degree peeling adhesive power to a silicon mirror wafer of a portion of the pressure-sensitive adhesive layer where a dicing ring is pasted is 1.0 N/20 mm tape width or more and 10.0 N/20 mm tape width or less under conditions of a measurement temperature of 23±3° C. and a tensile speed of 300 mm/min. Because the adhesive power is 1.0 N/20 mm tape width or more, the dicing die bond film can be kept from peeling from the dicing ring when dicing the semiconductor wafer. On the other hand, because the adhesive power is 10.0 N/20 mm tape width or less, the dicing film can be easily peeled from the dicing ring.

In the above-described configuration, the pressure-sensitive adhesive layer preferably further contains 5 to 10 parts by weight of an ultraviolet-ray curing-type oligomer component to 100 parts by weight of the polymer. The oligomer functions as a plasticizer on the portion of the pressure-sensitive adhesive layer that is not cured with an ultraviolet ray. As a result, high adhesive power can be maintained on the portion where the dicing ring is pasted, and adhesion to the dicing ring can be improved. On the other hand, because not only the polymer component but also the oligomer component is cured with an ultraviolet ray in the portion that is cured with an ultraviolet ray, adhesion to the die bond film can be kept low, and good pickup of the semiconductor chip can be achieved.

It is preferable that the irradiation with ultraviolet rays be conducted within a range from 30 to 1,000 mJ/cm². By adjusting the irradiation with ultraviolet rays to 30 mJ/cm² or more, the pressure-sensitive adhesive layer is sufficiently cured, thus preventing excessively adhering to the die bond film. As a result, satisfactory pickup properties can be obtained and attachment of the pressure-sensitive adhesive (so-called adhesive residue) on the die bond film after picking up can be prevented. In contrast, by adjusting the irradiation with ultraviolet rays to 1,000 mJ/cm² or less, thermal damage to the base material can be reduced. It is possible to prevent deterioration in the expansion property due to extremely increase in the tensile elastic modulus resulting from excessively curing of the pressure-sensitive adhesive layer. Furthermore, the adhesive power is prevented from becoming too low, thus making it possible to prevent the generation of chip fly when a workpiece is diced.

The hydroxyl group-containing monomer is at least anyone selected from the group consisting of 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate and (4-hydroxymethylcyclohexyl)methyl (meth)acrylate.

The isocyanate compound having a radical reactive carbon-carbon double bond is at least 2-methacryloyloxyethyl isocyanate or 2-acryloyloxyethyl isocyanate.

Further, the pressure-sensitive adhesive layer preferably does not contain acrylic acid. Whereby, the reaction and interaction between the pressure-sensitive adhesive layer and the die bond film can be prevented and thus pickup properties can be further improved.

In order to solve the above-described problems, the method of manufacturing a dicing die bond film according to the present invention is a method of manufacturing a dicing die bond film including a dicing film including a base and a pressure-sensitive adhesive layer provided thereon and a die bond film provided on the pressure-sensitive adhesive layer, and includes the steps of forming on the base a pressure-sensitive adhesive layer precursor that is constituted with a polymer formed by performing an addition reaction on an acrylic polymer containing 10 to 40 mol % of a hydroxyl group-containing monomer with an isocyanate compound having 70 to 90 mol % of a radical reactive carbon-carbon double bond with respect to the hydroxyl group-containing monomer, and a crosslinking agent having two or more functional groups exhibiting reactivity to a hydroxyl group and having a content of 0.5 to 2 parts by weight to 100 parts by weight of the polymer, forming a pressure-sensitive adhesive layer in which the 180 degree peeling adhesive power to a silicon mirror wafer of a portion of the pressure-sensitive adhesive layer where a dicing ring is pasted is 1.0 N/20 mm tape width or more and 10.0 N/20 mm tape width or less under conditions of a measurement temperature of 23±3° C. and a tensile speed of 300 mm and in which the tensile storage modulus at 23° C. of a portion where the dicing ring is pasted is 0.05 MPa or more and less than 0.4 MPa by irradiating the pressure-sensitive adhesive layer precursor with an ultraviolet ray under a prescribed condition, and pasting the die bond film onto the pressure-sensitive adhesive layer.

The pressure-sensitive adhesive layer of the dicing film is cured by ultraviolet irradiation in advance before bonding to the die bond film. Therefore, the surface of the pressure-sensitive adhesive layer is hard and is in a state where adhesion to unevenness has decreased. According to the present invention, the dicing die bond film is manufactured by bonding the die bond film on the pressure-sensitive adhesive layer. As a result, adhesion between the pressure-sensitive adhesive layer and the die bond film is decreased, thus decreasing the anchor effect, thus obtaining a dicing die bond film which is excellent in peeling property between the pressure-sensitive adhesive layer and the die bond film and exhibits satisfactory pickup properties, in the case of picking up the semiconductor chip, for example. When the pressure-sensitive adhesive layer is cured by ultraviolet irradiation, the volume of the pressure-sensitive adhesive layer decreases as a result of formation of a crosslinking structure. Therefore, when the pressure-sensitive adhesive layer is cured by ultraviolet irradiation after bonding with the die bond film, stress is applied to the die bond film. As a result, the entire dicing die bond film may undergo warpage. However, since the dicing die bond film of the present invention is formed by bonding with the die bond film after curing by ultraviolet irradiation, it is also possible to prevent unnecessary stress from applying on the die bond film. As a result, a dicing die bond film free from warpage can be obtained.

The constituent material of the pressure-sensitive adhesive layer contains, as an essential component, a crosslinking agent having two or more functional groups in the molecule, which exhibit reactivity with a hydroxyl group, and the tensile elastic modulus is adjusted by controlling the additive amount of the crosslinking agent so as to achieve satisfactory pickup properties while maintaining holding strength upon dicing. Because the content of the crosslinking agent of the present invention is 2 parts by weight or less to 100 parts by weight of the polymer, a decrease of the tensile storage modulus can be prevented by suppressing the crosslinking by an ultraviolet ray, and high adhesive power can be maintained. As a result, the dicing die bond film can be suppressed from being peeled from the dicing ring when dicing a semiconductor wafer. On the other hand, because the content is 0.5 parts by weight or more, the adhesive power can be preferably decreased by curing the portion that corresponds to the semiconductor wafer pasting portion with an ultraviolet ray. As a result, the pickup property during pickup of the semiconductor chip can be improved.

Furthermore, poor crosslinking after ultraviolet irradiation is suppressed by adjusting the content of a hydroxyl group-containing monomer to 10 mol % or more. As a result, it is possible to prevent deterioration of pickup properties. In contrast, by adjusting the content to 40 mol % or less, it is possible to prevent deterioration of pickup properties caused by the fact that the polarity of the pressure-sensitive adhesive becomes high and the interaction with the die bond film becomes intense, which makes it difficult to perform peeling. Decrease in productivity due to partial gelatinization of the polymer can be also prevented.

In the above-described configuration, the pressure-sensitive adhesive layer precursor may further contain 0 to 100 parts by weight of an ultraviolet-ray curing-type oligomer component to 100 parts by weight of the polymer. When forming the pressure-sensitive adhesive layer by irradiation with an ultraviolet ray, the oligomer functions as a plasticizer on the portion that is not irradiated with an ultraviolet ray. As a result, high adhesive power can be maintained on the portion where the dicing ring is pasted, and adhesion to the dicing ring can be improved. On the other hand, because not only the polymer component but also the oligomer component is cured with an ultraviolet ray in the portion that is irradiated with an ultraviolet ray, adhesion to the die bond film can be kept low, and good pickup of the semiconductor chip can be achieved.

It is preferable that the irradiation with ultraviolet rays be conducted within a range from 30 to 1,000 mJ/cm². By adjusting the irradiation with ultraviolet rays to 30 mJ/cm² or more, the pressure-sensitive adhesive layer is sufficiently cured, thus preventing excessively adhering to the die bond film. As a result, satisfactory pickup properties can be obtained and attachment of the pressure-sensitive adhesive (so-called adhesive residue) on the die bond film after picking up can be prevented. In contrast, by adjusting the irradiation with ultraviolet rays to 1,000 mJ/cm² or less, thermal damage to the base material can be reduced.

In order to solve the above-described problems, the method of manufacturing a semiconductor device according to the present invention is a method using a dicing die bond film with a dicing film including a base and a pressure-sensitive adhesive layer provided thereon and a die bond film provided on the pressure-sensitive adhesive layer, and includes the steps of preparing the above-described dicing die bond film and pasting the dicing ring to the portion of the pressure-sensitive adhesive layer where the dicing ring is pasted, pressure-bonding a semiconductor wafer onto the die bond film, forming a semiconductor chip by dicing the semiconductor wafer together with the die bond film, and peeling the semiconductor chip from the pressure-sensitive adhesive layer together with the die bond film, and in which the step of pressure-bonding the semiconductor wafer to the step of peeling the semiconductor chip are performed without irradiating the pressure-sensitive adhesive layer with an ultraviolet ray.

In the above method, a dicing die bond film, which prevents the generation of chip fly of a semiconductor chip and is also excellent in pickup properties, is used in the case of dicing a semiconductor wafer. Therefore, the semiconductor chip can be easily peeled off from the dicing film, together with the die bond film in the case of a large semiconductor chip measuring 10 mm×10 mm or more or an extremely thin semiconductor chip measuring 25 to 75 μm in thickness. By the above-described method, a semiconductor device can be manufactured with an improved yield.

Also, it is not necessary to irradiate the pressure-sensitive adhesive layer with ultraviolet rays before picking up. As a result, the number of steps can be decreased as compared with a conventional method of manufacturing a semiconductor device. Furthermore, the generation of defects of a circuit pattern caused by irradiation with ultraviolet rays can be prevented even if a semiconductor wafer has a predetermined circuit pattern. As a result, it becomes possible to manufacture a semiconductor device with high reliability.

In the above-described method, because the dicing die bond film as described above is prepared and the dicing ring is pasted to a portion of the pressure-sensitive adhesive layer where the dicing ring is pasted, the adhesive power of the portion where the dicing ring is pasted can be kept high, and the dicing die bond film can be suppressed from being peeled from the dicing ring when dicing the semiconductor wafer.

### BRIEF DESCRIPTION OF THE DRAWINGS

FIG. 1 is a schematic sectional view showing a dicing die bond film according to one embodiment of the present invention;

FIG. 2 is a schematic sectional view showing another dicing die bond film according to another embodiment of the present invention; and

FIGS. 3A to 3E are schematic sectional views showing an example in which a semiconductor chip is mounted with a die bond film of the dicing die bond film shown in FIG. 2 interposed in between.

### DESCRIPTION OF THE REFERENCE NUMERALS

1 base
2 pressure-sensitive adhesive layer
3 die bond film
4 semiconductor wafer
5 semiconductor chip
6 adherend
7 bonding wire
8 sealing resin
9 heat block
10, 11 dicing die bond film

### DETAILED DESCRIPTION OF PREFERRED EMBODIMENTS

### Dicing Die Bond Film

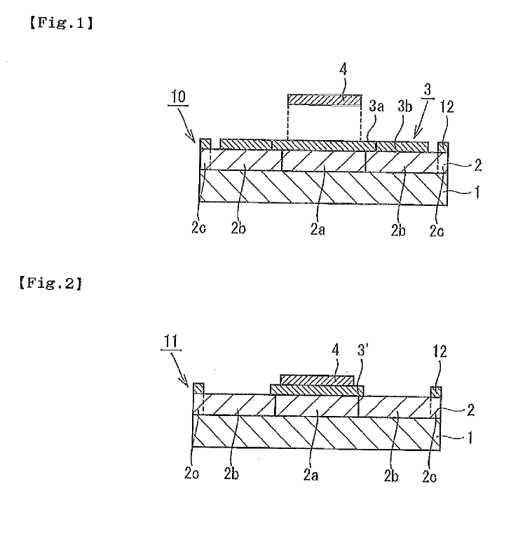

The embodiment of the present invention is described referring to FIGS. 1 and 2. FIG. 1 is a cross-sectional schematic drawing showing a dicing die bond film according to the present embodiment. FIG. 2 is a cross-sectional schematic drawing showing another dicing die bond film according to the present embodiment. However, parts that are unnecessary for the description are not given, and there are parts shown by magnifying, minifying, etc. in order to make the description easy.

As shown in FIG. 1, a dicing die bond film 10 has a configuration having a dicing film in which a pressure sensitive adhesive layer 2 is provided on a base material 1 and a die bond film 3 is provided on the pressure sensitive adhesive layer 2. The pressure-sensitive adhesive layer 2 has a portion 2a that corresponds to a semiconductor wafer pasting portion 3a, a portion 2c where a dicing ring 12 is pasted, and a portion 2b other than these portions. The die bond film may be pasted to a portion other than the portion 2c of the pressure-sensitive adhesive layer 2, and the dicing die bond film may have a configuration in which a die bond film 3′ is formed only on the semiconductor wafer pasting portion as shown in FIG. 2, for example.

The base material 1 has ultraviolet ray transmission and is a strength matrix of the dicing die bond films 10, 11. Examples thereof include polyolefin such as low-density polyethylene, straight chain polyethylene, intermediate-density polyethylene, high-density polyethylene, very low-density polyethylene, random copolymer polypropylene, block copolymer polypropylene, homopolypropylene, polybutene, and polymethylpentene; an ethylene-vinylacetate copolymer; an ionomer resin; an ethylene (meth)acrylic acid copolymer; an ethylene (meth)acrylic acid ester (random or alternating) copolymer; an ethylene-butene copolymer; an ethylene-hexene copolymer; polyurethane; polyester such as polyethyleneterephthalate and polyethylenenaphthalate; polycarbonate; polyetheretherketone; polyimide; polyetherimide; polyamide; whole aromatic polyamides; polyphenylsulfide; aramid (paper); glass; glass cloth; a fluorine resin; polyvinyl chloride; polyvinylidene chloride; a cellulose resin; a silicone resin; metal (foil); and paper.

Further, the material of the base material 1 includes a polymer such as a cross-linked body of the above resins. The above plastic film may be also used unstreched, or may be also used on which a monoaxial or a biaxial stretching treatment is performed depending on necessity. According to resin sheets in which heat shrinkable properties are given by the stretching treatment, etc., the adhesive area of the pressure sensitive adhesive layer 2 and the die bond films 3, 3′ is reduced by thermally shrinking the base material 1 after dicing, and the recovery of the semiconductor chips can be facilitated.

A known surface treatment such as a chemical or physical treatment such as a chromic acid treatment, ozone exposure, flame exposure, high voltage electric exposure, and an ionized radiation treatment, and a coating treatment by an undercoating agent (for example, a tacky substance described later) can be performed on the surface of the base material 1 in order to improve adhesiveness, holding properties, etc. with the adjacent layer.

The same type or different type of base material can be appropriately selected and used as the base material 1, and a base material in which a plurality of types are blended can be used depending on necessity. Further, a vapor-deposited layer of a conductive substance composed of a metal, an alloy, an oxide thereof, etc. and having a thickness of about 30 to 500 angstrom can be provided on the base material 1 in order to give an antistatic function to the base material 1. The base material 1 may be a single layer or a multi layer of two or more types.

The thickness of the base material 1 can be appropriately decided without limitation particularly. However, it is generally about 5 to 200 μm.

The pressure-sensitive adhesive layer 2 is formed from an ultraviolet-ray curing-type pressure-sensitive adhesive, and it is cured by the ultraviolet irradiation in advance. The cured portion is not necessarily the entire region of the pressure-sensitive adhesive layer 2, and at least a portion 2a corresponding to a semiconductor wafer attaching portion 3a of the pressure-sensitive adhesive layer 2 may be cured (see FIG. 1). Since the pressure-sensitive adhesive layer 2 is cured by the ultraviolet irradiation before bonding with a die bond film 3, the surface thereof is hard, and the excessively high adhesion is suppressed at the interface between the pressure-sensitive adhesive layer 2 and the die bond film 3. Thus, the anchor effect between the pressure-sensitive adhesive layer 2 and the die bond film 3 is decreased, and the peeling property can be improved. On the other hand, the portions 2b and 2c of the pressure-sensitive adhesive layer 2 are uncured because they are not irradiated with an ultraviolet ray, and have a larger than that of the portion 2a. Accordingly, when the dicing ring 12 is pasted to the portion 2c, the dicing ring 12 can be certainly adhered and fixed.

By curing the ultraviolet-ray curing-type pressure-sensitive adhesive layer 2 matching in the shape of a die bond film 3′ shown in FIG. 2 in advance, excessively high adhesion is suppressed at the interface between the pressure-sensitive adhesive layer 2 and the die bond film 3. Thus, the die bond film 3′ has a characteristic of peeling easily off the pressure-sensitive adhesive layer 2 upon picking up. On the other hand, the portions 2b and 2c of the pressure-sensitive adhesive layer 2 are uncured because they are not irradiated with an ultraviolet ray, and have an adhesive power larger than that of the portion 2a. Accordingly, the dicing ring 12 can be certainly adhered and fixed when the dicing ring 12 is pasted to the portion 2c.

As described above, in the pressure sensitive adhesive layer 2 of the dicing die bond film 10 shown in FIG. 1, the part 2b formed by a non-cured ultraviolet ray curable pressure sensitive adhesive sticks to the die bond film 3, and the holding force when dicing can be secured. In such a way, the ultraviolet ray curable pressure sensitive adhesive can support the die bond film 3 for fixing the semiconductor chip onto an adherend such as a substrate with good balance of adhesion and peeling. The portion 2c can fix the dicing ring in the pressure-sensitive adhesive layer 2 of the dicing die bond film 10 shown in FIG. 1 and of the dicing die bond film 11 shown in FIG. 2. The dicing ring made of a metal such as stainless steel or a resin can be used for example.

The tensile storage modulus at 23° C. of the portion 2c where the dicing ring is pasted in the dicing die bond films 10 and 11 is 0.05 MPa or more and less than 0.4 MPa. Because the tensile storage modulus is less than 0.4 MPa, the adhesive power can be kept high, and peeling of the dicing die bond films 10 and 11 from the dicing ring can be suppressed when dicing a semiconductor wafer. On the other hand, because the tensile storage modulus is 0.05 MPa or more, generation of adhesive residue can be prevented when peeling the dicing film from the dicing ring.

The tensile storage modulus at 23° C. of the dicing die bond films 10 and 11 after curing of the portion 2a is preferably 5 MPa or more and 100 MPa or less, and more preferably 7 MPa or more and 80 MPa or less.

The 180 degree peeling adhesive power to a silicon mirror wafer of the portion 2c of the dicing die bond films 10 and 11 where a dicing ring is pasted is 1.0 N/20 mm tape width or more and 10.0 N/20 mm tape width or less under conditions of a measurement temperature of 23±3° C. and a tensile speed of 300 mm/min. Because the adhesive power is 1.0 N/20 mm tape width or more, peeling of the dicing die bond films 10 and 11 from the dicing ring can be suppressed when dicing the semiconductor wafer. On the other hand, because the adhesive power is 10.0 N/20 mm tape width or less, the dicing film can be easily peeled from the dicing ring.

In the dicing die bond film 10, the adhesive power of the portion 2a in the pressure-sensitive adhesive layer 2 to the semiconductor wafer attaching portion 3a is preferably designed to be smaller than the adhesive power of the other portion 2b to a portion 3b that differs from the semiconductor wafer attaching portion 3a. The adhesive power of the portion 2a under the condition of a normal temperature of 23° C., a peeling angle of 15 degrees, and a peeling rate of 300 mm/min is preferably 0.5 to 1.5 N/10 mm from the viewpoints of fixing and holding strength of the wafer, recovering property of a chip that is formed. When the adhesive power is less than 0.5 N/10 mm, the adhesion and fixing of a semiconductor chip becomes insufficient, and therefore chip fly may be generated upon dicing. When the adhesive power exceeds 1.5 N/10 mm, the pressure-sensitive adhesive layer 2 excessively adheres to the die bond film 3, and therefore the picking up of the semiconductor chip may become difficult. On the other hand, the adhesive power of the other portion 2b is preferably from 0.5 to 10 N/10=, and more preferably from 1 to 5 N/10 mm. Even when the portion 2a has low adhesive power, the generation of chip fly can be suppressed by the adhesive power of the other portion 2b, and the holding strength that is necessary for a wafer process can be exhibited.

In the dicing die bond film 11, the adhesive power of the portion 2a in the pressure-sensitive adhesive layer 2 to the semiconductor wafer attaching portion 3a is preferably designed to be smaller than the adhesive power of the portion 2b to a dicing ring 12. The adhesive power of the portion 2a to the semiconductor wafer attaching portion 3a (under the same conditions as described above) is preferably 0.5 to 1.5 N/10 mm as the same as described above. On the other hand, the adhesive power of the other portion 2b to the dicing ring 12 is preferably from 0.05 to 10 N/10 mm, and more preferably from 0.1 to 5 N/10 mm. Even when the portion 2a has low peeling adhesive power, the generation of chip fly can be suppressed by the adhesive power of the other portion 2b, and the holding strength that is sufficient for a wafer process can be exhibited. These adhesive powers are based on a measured value at a normal temperature of 23° C., a peeling angle of 180 degrees, and a tensile speed of 300 mm/min.

In the dicing die bond films 10, 11, the adhesive power of the wafer attaching portion 3a to the semiconductor wafer is preferably designed to be larger than the adhesive power of the wafer attaching portion 3a to the portion 2a. The adhesive power to the semiconductor wafer is appropriately adjusted depending on its type. The adhesive power of the semiconductor wafer attaching portion 3a to the portion 2a (under the same conditions as described above) is preferably from 0.05 to 10 N/10 mm, and more preferably from 0.1 to 5 N/10 mm. On the other hand, the adhesive power of the semiconductor wafer attaching portion 3a to the semiconductor wafer (under the same conditions as described above) is preferably from 0.5 to 15 N/10 mm, and more preferably from 1 to 15 N/10 mm from the viewpoints of reliability upon dicing, picking up and die bonding as well as the pickup properties.

It is preferred to satisfy a relationship of r₁<r₂<r₃, where r₁ is the diameter of a semiconductor wafer 4, r₂ is the diameter of the portion 2a in the pressure-sensitive adhesive layer 2, and r₃ is the diameter of the semiconductor wafer attaching portion 3a in the die bond film 3 (or the die bond film 3′). Thus, the entire face of the semiconductor wafer 4 can be adhered and fixed onto the die bond films 3, 3′, and the peripheral part of the semiconductor wafer attaching portion 3a (or the die bond film 3′) can be adhered and fixed to the other portion 2b. Since the adhesive power of other portion 2b is higher than that of the portion 2a, the semiconductor wafer attaching portion 3a (or the die bond film 3′) can be adhered and fixed at the peripheral part. As a result, the generation of chip fly can be further prevented upon dicing.

The ultraviolet ray curable pressure sensitive adhesive that is used has a ultraviolet ray curable functional group of a radical reactive carbon-carbon double bond, etc., and adherability. Examples of the ultraviolet ray curable pressure sensitive adhesive are an added type ultraviolet ray curable pressure sensitive adhesive in which a ultraviolet ray curable monomer component or an oligomer component is compounded into an acryl pressure sensitive adhesive. Among these, an ultraviolet-ray curing-type pressure-sensitive adhesive is preferable in which an ultraviolet-ray curing-type oligomer component is compounded. The acryl pressure sensitive adhesive is a pressure sensitive adhesive having an acryl polymer as a base polymer, and it is preferable in the respect of purifying and cleaning properties, etc. of electric parts that have to be kept away from contamination such as a semiconductor wafer and a glass with ultra pure water and an organic solvent such as alcohol.

Examples of the acrylic polymer include acrylic polymers using, as a monomer component, one or more kinds of (meth) acrylic acid alkyl esters (for example, linear or branched alkyl esters whose alkyl group has 1 to 30 carbon atoms, especially 4 to 18 carbon atoms, such as methyl ester, ethyl ester, propyl ester, isopropyl ester, butyl ester, isobutyl ester, sec-butyl ester, t-butyl ester, pentyl ester, isopentyl ester, hexyl ester, heptyl ester, octyl ester, 2-ethylhexyl ester, isooctyl ester, nonyl ester, decyl ester, isodecyl ester, undecyl ester, dodecyl ester, tridecyl ester, tetradecyl ester, hexadecyl ester, octadecyl ester, eicosyl ester, etc.) and (meth)acrylic acid cycloalkyl esters (for example, cyclopentyl ester, cyclohexyl ester, etc.). The (meth)acrylic acid ester means an acrylic acid ester and/or a methacrylic acid ester, and has very the same meaning as (meth) in the present invention.

The acryl polymer contains a hydroxyl group-containing monomer copolymerizable with the acrylate as an essential component. Examples of the hydroxyl group-containing monomer include 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl)methyl(meth)acrylate.

The content of the hydroxyl group-containing monomer is preferably within a range from 10 to 40 mol %, and more preferably from 15 to 30 mol % based on the acrylic acid ester. When the content is less than 10 mol %, crosslinking after ultraviolet irradiation becomes insufficient and pickup properties may deteriorate. In contrast, when the content exceeds 40 mol %, peeling becomes difficult because the polarity of the pressure-sensitive adhesive becomes high and the interaction with the die bond film becomes intense.

The acryl polymer may contain a unit corresponding to other monomer components copolymerizable with the alkyl acrylate or cycloalkylester depending on necessity for the purpose of modification of cohesion force, heat resistance, etc. Examples of such monomer components include a carboxyl group-containing monomer such as acrylic acid, methacrylic acid, carboxyethyl(meth)acrylate, carboxypentyl(meth)acrylate, itaconic acid, maleic acid, fumaric acid, and crotonic acid; an acid anhydride monomer such as maleic anhydride and itaconic anhydride; a sulfonic acid group-containing monomer such as styrenesulfonic acid, allylsulfonic acid, 2-(meth)acrylamide-2-methylpropanesulfonic acid, (meth)acrylicamidepropanesulfonic acid, sulfopropyl(meth)acrylate, and (meth)acryloyloxynaphthalenesulfonic acid; a phosphoric acid containing monomer such as 2-hydroxyethylacryloylphosphate; acrylamide; and acrylonitrile. One type or two types or more of these copolymerizable monomer components can be used. The use amount of these copolymerizable monomers is preferably 40% by weight or less of the entire monomer components. However, in the case of the carboxyl group-containing monomer, an interface between the pressure sensitive adhesive layer 2 and the die bond film 3 disappears when the carboxyl group reacts with an epoxy group in an epoxy resin in the die bond film 3, and the peeling property of both may decrease. Therefore, the use amount of the carboxyl group-containing monomer is preferably 0 to 3% by weight of the entire monomer component. Additionally, because the hydroxyl group-containing monomer and a glycidyl group-containing monomer can also react with the epoxy group in the epoxy resin, the use amounts of these are preferably made to be the same as the case of the carboxyl group-containing monomer. Further, among these monomer components, the pressure sensitive adhesive layer 2 of the present invention does not preferably contain acrylic acid. The reason is that there is the case where acrylic acid reacts or interacts with the die bond film 3, resulting in deterioration of peeling property.

Here, the acryl polymer does not contain a polyfunctional monomer as the monomer component for copolymerization. Accordingly, the polyfunctional monomer does not undergo mass diffusion to the die bond film, and the decrease in the pickup properties is prevented, caused by disappearing the interface between the pressure sensitive adhesive layer 2 and the die bond film 3.

Further, the acryl polymer may contain an isocyanate compound having a radical reactive carbon-carbon double bond. Examples of the isocyanate compound include methacryloylisocyanate, 2-methacryloyloxyethylisocyanate, 2-acryloyloxyethylisocyanate, and m-isopropenyl-α,α-dimethylbenzylisocyanate.

The content of the isocyanate compound having a radical reactive carbon-carbon double bond is preferably within a range from 70 to 90 mol %, and more preferably from 75 to 85 mol %, based on the hydroxyl group-containing monomer. When the content is less than 70 mol %, adhesive residue occurs on a dicing ring to be bonded on the pressure-sensitive adhesive layer upon dicing because of poor crosslinking after ultraviolet irradiation. In contrast, when the content exceeds 90 mol %, the polarity of the pressure-sensitive adhesive becomes high and the interaction with the die bond film becomes intense, which makes it difficult to perform satisfactory peeling.

The acrylic polymer can be obtained by polymerizing a monomer alone or a mixture of two or more kinds of monomers. The polymerization can be conducted by any of methods such as solution polymerization, emulsion polymerization, bulk polymerization and suspension polymerization. The content of a low-molecular weight material is preferably small from the viewpoint of preventing contamination of a clean adherend. In this respect, the weight average molecular weight of the acrylic polymer is preferably from 350,000 to 1,000,000, and more preferably from about 450,000 to 800,000.

The pressure-sensitive adhesive layer 2 contains a crosslinking agent including in the molecule two or more functional groups having reactivity with a hydroxyl group. Examples of the functional group which exhibits reactivity with a hydroxyl group include an isocyanate group, an epoxy group and a glycidyl group. More specifically, an isocyanate based crosslinking agent, an epoxy based crosslinking agent, an aziridine based crosslinking agent and a melamine based crosslinking agent are exemplified as the crosslinking agent having such a functional group. Among these, an isocyanate crosslinking agent is preferable.

The isocyanate based crosslinking agent is not particularly limited as long as it has two or more isocyanate groups in the molecule, and examples thereof include toluene diisocyanate, diphenylmethane diisocyanate and hexamethylene diisocyanate. These isocyanate based crosslinking agents may be used alone, or two or more kinds thereof may be used in combination.

The epoxy based crosslinking agent is not particularly limited as long as it has two or more epoxy groups in the molecule, and examples thereof include ethylene glycol diglycidyl ether, sorbitol polyglycidyl ether, polyglycerol polyglycidyl ether, diglycerol polyglycidyl ether, glycerol polyglycidyl ether and resorcin diglycidyl ether. These epoxy based crosslinking agents may be used alone, or two or more kinds thereof may be used in combination.

The aziridine based crosslinking agent is not particularly limited as long as it has two or more aziridine groups in the molecule. For example, ω-aziridinylpropionic acid-2,2-dihydroxymethyl-butanol-triester, 4,4′-bis(ethyleneiminocarbonylamino)diphenylmethane, 2,4,6-(triethyleneimino)-sym-triazine, and 1,6-bis(ethyleneiminocarbonylamino)hexane are preferably used. These aziridine based crosslinking agents may be used alone, or two or more kinds thereof may be used in combination.

The content of the crosslinking agent is 0.5 to 2 parts by weight to 100 parts by weight of the base polymer. The content of the crosslinking agent is preferably in a range of 0.5 to 1.0 part by weight. Because the content is 2 parts by weight or less, a decrease of the tensile storage modulus is prevented by suppressing the crosslinking with an ultraviolet ray, and the adhesive power can be kept high. As a result, the dicing die bond films 10 and 11 can be suppressed from peeling from the dicing ring when dicing a semiconductor wafer. On the other hand, because the content is 0.5 parts by weight or more, generation of adhesive residue when peeling the dicing film from the dicing ring can be prevented. Additives such as various conventionally known tackifiers and anti-aging agents may be used in the pressure-sensitive adhesive other than the above-described components as necessary.

Examples of the ultraviolet curable monomer component to be compounded include such as an urethane oligomer, urethane(meth)acrylate, trimethylolpropanetri(meth)acrylate, tetramethylolmethane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butane dioldi(meth)acrylate. Further, the ultraviolet curable oligomer component includes various types of oligomers such as an urethane based, a polyether based, a polyester based, a polycarbonate based, and a polybutadiene based oligomer, and its molecular weight is appropriately in a range of about 100 to 30,000. The compounded amount of the ultraviolet-ray curing-type monomer component and oligomer component is preferably 0 to 100 parts by weight, and more preferably 10 to 50 parts by weight to 100 parts by weight of a base polymer such as an acrylic polymer that constitutes the pressure-sensitive adhesive. The oligomer functions as a plasticizer in the portion (the portions 2b and 2c) that are not cured with an ultraviolet ray in the pressure-sensitive adhesive layer 2. As a result, the adhesive power can be kept high in the portion 2c where the dicing ring is pasted, and the adhesion to the dicing ring can be improved. On the other hand, because not only the polymer component but also the oligomer component are cured by an ultraviolet ray in the portion (the portion 2a) that is cured by an ultraviolet ray, the adhesion to the die bond films 3 and 3′ can be kept low and good pickup of the semiconductor chip can be obtained.

Further, besides the added type ultraviolet ray curable pressure sensitive adhesive described above, the ultraviolet ray curable pressure sensitive adhesive includes an internal ultraviolet ray curable pressure sensitive adhesive using a polymer having a radical reactive carbon-carbon double bond in the polymer side chain, in the main chain, or at the end of the main chain as the base polymer. The internal ultraviolet curable pressure sensitive adhesives of an internally provided type are preferable because they do not have to contain the oligomer component, etc. that is a low molecular weight component, or most of them do not contain, they can form a pressure sensitive adhesive layer having a stable layer structure without migrating the oligomer component, etc. in the pressure sensitive adhesive over time.

As the base polymer having a radical reactive carbon-carbon double bond, for example, those having a radical reactive carbon-carbon double bond and having adhesion can be used without any limitation. The base polymer preferably has an acrylic polymer as a basic skeleton. As the basic skeleton of the acrylic polymer, the acrylic polymers listed above are exemplified.

The method of introducing the radical reactive carbon-carbon double bond into the acryl polymer is not particularly limited, and various methods can be adopted. However, it is easy to introduce the radical reactive carbon-carbon double bond into the polymer side chain from the viewpoint of a molecular design. For example, a method of copolymerizing a monomer having a hydroxyl group with the acryl polymer in advance and then performing a condensation or an addition reaction on an isocyanate compound having an isocyanate group that can react with this hydroxyl group and a radical reactive carbon-carbon double bond while keeping ultraviolet ray curability of the radical reactive carbon-carbon double bond. Examples of the isocyanate compound having an isocyanate group and a radical reactive carbon-carbon double bond include those exemplified above. Further, those in which the exemplified hydroxyl group-containing monomer and an ether based compound such as 2-hydroxyethylvinylether, 4-hydroxybutylvinylether, and diethylene glycol monovinylether, etc. are copolymerized can be used as the acryl polymer.

In the internal type ultraviolet-ray curing-type pressure-sensitive adhesive, the base polymer (especially an acrylic polymer) having a radical reactive carbon-carbon double bond can be used alone. However, an ultraviolet-ray curable monomer component and an oligomer component may also be mixed as long as characteristics do not deteriorate. The amount of the ultraviolet-ray curable oligomer component is usually from 5 to 500 parts by weight, and preferably from 40 to 150 parts by weight, based on 100 parts by weight of the base polymer.

A photopolymerization initiator is contained in the internal ultraviolet ray curable pressure sensitive adhesive in the case of curing with radiation such as ultraviolet rays. Examples of the photopolymerization initiator include an α-ketol based compound such as 4-(2-hydroxyethoxy)phenyl (2-hydroxy-2-propyl)ketone, α-hydroxy-α,α′-dimethylacetophenone, 2-methyl-2-hydroxypropyophenone, and 1-hydroxycyclohexylphenylketone; an acetophenone based compound such as methoxyacetophenone, 2,2-dimethoxy-2-phenylacetophenone, 2,2-diethoxyacetophenone, and 2-methyl-1-[4-(methylthio)-phenyl]-2-morpholinopropane-1; a benzoinether based compound such as benzoinethylether, benzoinisopropylether, and anisoinmethylether; a ketal based compound such as benzyldimethylketal; an aromatic sulfonylchloride based compound such as 2-naphthalenesulfonylchloride; a photoactive oxime based compound such as 1-phenone-1,1-propanedion-2-(o-ethoxycarbonyl)oxime; a benzophenone based compound such as benzophenone, benzoylbenzoic acid and 3,3′-dimethyl-4-methoxybenzophenone; a thioxanthone based compound such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketone; acylphosphinoxide; acylphosphonate and the like. The compounding amount of the photopolymerization initiator is about 0.05 to 20 parts by weight for example based on 100 parts by weight of the base polymer such as an acryl polymer constituting the pressure sensitive adhesive.

Further, examples of the ultraviolet ray curable pressure sensitive adhesive include a rubber based pressure sensitive adhesive and acryl-based pressure sensitive adhesive containing an addition polyerizable compound having two or more unsaturated bonds, a photopolymerizable compound such as alkoxysilane having an epoxy group, and a photopolymerization initiator such as a carbonyl compound, an organic sulfur compound, a peroxide, an amine and an onium salt based compound, which are disclosed in JP-A No. 60-196956.

In the pressure-sensitive adhesive layer 2 of the dicing die bond film 10, a part of the pressure-sensitive adhesive layer 2 may be irradiated with ultraviolet rays so that the adhesive power of the portion 2a becomes smaller than the adhesive power of the other portion 2b. That is, the portion 2a can be formed where the adhesive power is reduced by using the base material 1 of which the entire or a part of the portion other than the portion corresponding to the semiconductor wafer attaching portion 3a on at least one side of the base material 1 is shielded, forming the ultraviolet-ray curing-type pressure-sensitive adhesive layer 2 onto the base material 1, and then curing the portion corresponding to the semiconductor wafer attaching portion 3a by ultraviolet irradiation. As the shielding material, a material that can serve as a photo mask on a support film can be manufactured by printing or vapor deposition.

When an impediment to curing due to oxygen occurs during the ultraviolet irradiation, it is desirable to shut off oxygen (air) from the surface of the ultraviolet-ray curing-type pressure-sensitive adhesive layer 2. Examples of the shut-off method include a method of coating the surface of the pressure-sensitive adhesive layer 2 with a separator and a method of conducting irradiation with ultraviolet rays in a nitrogen gas atmosphere.

The thickness of the pressure sensitive adhesive layer 2 is not particularly limited. However, it is preferably about 1 to 50 μm from the viewpoints of compatibility of chipping prevention of the chip cut face and holding the fixation of the adhesive layer, etc. It is preferably 2 to 40 μm, and further preferably 5 to 30 μm.

The die bond films 3, 3′ can have a configuration consisting of only a single layer of the adhesive layer, for example. Further, it may have a multi-layered structure of two layers or more by appropriately combining a thermoplastic resin having a different glass transition temperature and a thermosetting resin having a different heat curing temperature. Here, because cutting water is used in the dicing step of the semiconductor wafer, there is a case where the die bond films 3, 3′ absorbs moisture and moisture content becomes a normal condition or more. When the die bond films 3, 3′ is adhered to a substrate etc. with such high moisture content, water vapor is accumulated on an adhering interface in the step after curing, and there is a case where floating is generated. Therefore, by making the adhesive for die adhering have a configuration of sandwiching a core material having high moisture permeability with die adhesives, water vapor diffuses through the film in the step after curing, and such problem can be avoided. From such a viewpoint, the die bond film 3 may have a multi-layered structure in which the adhesive layer is formed on one face or both faces of the core material.

Examples of the core materials include such as a film (for example, a polyimide film, a polyester film, a polyethyleneterephthalate film, a polyethylenenaphthalate film, a polycarbonate film, etc.), a resin substrate reinforced with a glass fiber or a plastic nonwoven fiber, a silicon substrate, and a glass substrate.

The die bond films 3, 3′ according to the present invention is constituted by containing an epoxy resin as a main component. The epoxy resin is preferable from the viewpoint of containing fewer ionic impurities, etc. that corrode a semiconductor element. The epoxy resin is not particularly limited as long as it is generally used as an adhesive composition, and for example, a difunctional epoxy resin and a polyfunctional epoxy resin of such as a bispehnol A type, a bisphenol F type, a bisphenol S type, a brominated bisphenol A type, a hydrogenated bisphenol A type, a bisphenol AF type, a biphenyl type, a naphthalene type, a fluorine type, a phenol novolak type, an ortho-cresol novolak type, a trishydroxyphenylmethane type, and a tetraphenylolethane type epoxy resin or an epoxy resin of such as a hydantoin type, a trisglycidylisocyanurate type and a glycidylamine type epoxy resin are used. These can be used alone or two or more types can be used in combination. Among these epoxy resins, a novolak type epoxy resin, a biphenyl type epoxy resin, a trishydroxyphenylmethane type resin, and a tetraphenylolethane type epoxy resin are particularly preferable. This is because these epoxy resins have high reactivity with a phenol resin as a curing agent, and are superior in heat resistance, etc.

Further, other thermosetting resins or thermoplastic resins can be used together in the die bond films 3, 3′ depending on necessity. Examples of the thermosetting resin include such as a phenol resin, an amino resin, an unsaturated polyester resin, a polyurethane resin, a silicone resin, and a thermosetting polyimide resin. These resins can be used alone or two or more types can be used in combination. Further, the curing agent of the epoxy resin is preferably a phenol resin.

Furthermore the phenol resin acts as a curing agent of the epoxy resin, and examples include a novolak type phenol resin such as a phenol novolak resin, a phenol aralkyl resin, a cresol novolak resin, a tert-butylphenol novolak resin, and a nonylphenol novolak resin; a resol type phenol resin; and polyoxystyrene such as polyparaoxystyrene. These can be used alone or two or more types can be used in combination. Among these phenol resins, a phenol novolak resin and a phenolaralkyl resin are particularly preferable. This is because connection reliability of the semiconductor device can be improved.

The compounding ratio of the epoxy resin and the phenol resin is preferably made, for example, such that the hydroxy group in the phenol resin becomes 0.5 to 2.0 equivalent per equivalent of epoxy group in the epoxy resin component. It is more preferably 0.8 to 1.2 equivalent. That is, when the both compounding ratio becomes outside of the range, a sufficient curing reaction does not proceed, and the characteristics of the epoxy resin cured product easily deteriorate.

Examples of the thermoplastic resin include a natural rubber, a butyl rubber, an isoprene rubber, a chloroprene rubber, an ethylene-vinylacetate copolymer, an ethylene-acrylic acid copolymer, an ethylene-acrylate copolymer, a polybutadiene resin, a polycarbonate resin, a thermoplastic polyimide resin, a polyamide resin such as 6-nylon and 6,6-nylon, a phenoxy resin, an acrylic resin, a saturated polyester resin such as PET and PBT, a polyamideimide resin, and a fluorine resin. These thermoplastic resins can be used alone or two type or more can be used in combination. Among these thermoplastic resins, the acrylic resin is particularly preferable in which the ionic impurities are less, the heat resistance is high, and reliability of the semiconductor element can be secured.

The acrylic resin is not particularly limited, and examples include such as polymers having one type or two types or more of acrylic acid or methacrylic ester having a straight chain or branched alkyl group having 30 or more carbon atoms, particularly 4 to 18 carbon atoms as a component. Examples of the alkyl group include a methyl group, an ethyl group, a propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group, and a dodecyl group.

Further, other monomers forming the polymers are not particularly limited, and examples include a carboxyl group-containing monomer such as acrylic acid, methacrylic acid, carboxylethylacrylate, carboxylpentylacrylate, itaconic acid, maleic acid, fumaric acid, and chrotonic acid; an acid anhydride monomer such as maleic anhydride and itaconic anhydride; a hydroxyl group-containing monomer such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl)-methylacrylate; a sulfonic acid-containing monomer such as styrenesulfonic acid, allylsulfonic acid, 2-(meth)acrylamide-2-methylpropanesulfonic acid, (meth)acrylamidepropane sulfonic acid, sulfopropyl(meth)acrylate, and (meth) acryloyloxynaphthalene sulfonic acid; and a phosphoric acid-containing monomer such as 2-hydroxyethylacryloylphosphate.

Because the crosslinking is performed in the adhesive layer of the die bond films 3, 3′ to some extent in advance, a polyfunctional compound that reacts with a functional group at the end of molecular chain of the polymer is preferably added as a crosslinking agent when producing. Accordingly, the adhesive characteristic under high temperature is improved, and the improvement of the heat resistance is attempted.

Here, other additives can be appropriately compounded in the adhesive layer of the die bond films 3, 3′ depending on necessity. Examples of the other additives include a flame retardant, a silane coupling agent, and an ion trapping agent. Examples of the flame retardant include antimony trioxide, antimony pentoxide, a brominated epoxy resin. These can be used alone or two or more types can be used in combination. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These compounds can be used alone or two or more types can be used in combination. Examples of the ion trapping agents include hydrotalcites and bismuth hydroxide. These can be used alone or two or more types can be used in combination.

The thickness of the die bond films 3, 3′ is not particularly limited. However, it is about 5 to 100 μm, and preferably about 5 to 50 μm.

The dicing die bond films 10, 11 can be made to have an antistatic function. Accordingly, the circuit can be prevented from breaking down due to the generation of electrostatic energy during adhesion and peeling thereof and charging of a workpiece (a semiconductor wafer, etc.) by electrostatic energy or the like. Imparting the antistatic function can be performed with an appropriate manner such as a method of adding an antistatic agent or a conductive substance to the base material 1, the pressure sensitive adhesive layer 2, and the die bond films 3, 3′ and providing of a conductive layer composed of a charge-transfer complex, a metal film, etc. to the base material 1. These methods are preferably a method of which an impurity ion is difficult to generate, which impurity ion might change quality of the semiconductor wafer. Examples of the conductive substance (conductive filler) to be compounded for the purpose of imparting conductivity, improving thermal conductivity, etc. include a sphere-shaped, a needle-shaped, a flake-shaped metal powder such as silver, aluminum, gold, copper, nickel, and conductive alloy; a metal oxide such as alumina; amorphous carbon black, and graphite. However, the die bond films 3, 3′ are preferably non-conductive from the viewpoint of having no electric leakage.

The die bond films 3, 3′ of the dicing die bond films 10, 11 are preferably protected by a separator (not shown). The separator has a function as a protecting material that protects the die bond films 3, 3′ until they are practically used. Further, the separator can be used as a supporting base material when transferring the die bond films 3, 3′ to the pressure sensitive adhesive layer 2. The separator is peeled when pasting a workpiece onto the die bond films 3, 3′ of the dicing die bond film. Polyethylenetelephthalate (PET), polyethylene, polypropylene, a plastic film, a paper, etc. whose surface is coated with a peeling agent such as a fluorine based peeling agent and a long chain alkylacrylate based peeling agent can be also used as the separator.

### Producing Method of Dicing Die Bond Film

Next, the producing method of the dicing die bond film of the present invention is described with the dicing die bond film 10 as an example. First, the base material 1 can be formed with a conventionally known film producing method. Examples of the film-forming method include such as a calendar film-forming method, a casting method in an organic solvent, an inflation extrusion method in a closely sealed system, a T-die extrusion method, a co-extruding method, and a dry laminating method.

Next, a composition containing a pressure-sensitive adhesive is coated on a base material 1 and dried (while heat-crosslinking as necessary) to form a pressure-sensitive adhesive layer 2. Examples of the coating method include roll coating, screen coating, and gravure coating. The composition may be directly coated on the base material 1 or, after coating on a sheet of release paper having a surface subjected to a release treatment, the resultant coating film may be transferred onto the base material 1.

Next, a pressure-sensitive adhesive layer precursor is formed by coating a pressure-sensitive adhesive composition on the base material 1 to form a coating film and drying (by heat-crosslinking as necessary) the coating film under a prescribed condition. The coating method is not especially limited, and examples thereof include roll coating, screen coating, and gravure coating. The drying condition can be set variously depending on the thickness, the material, and the like of the coating film. Specifically, drying is conducted under the conditions of a drying temperature of 80 to 150° C. and a drying time of 0.5 to 5 minutes. The pressure-sensitive adhesive layer precursor may be formed by coating the pressure-sensitive adhesive composition on a separator to form a coating film and drying the coating film under the above condition. Then, the pressure-sensitive adhesive layer precursor is transferred onto the base material 1. The pressure-sensitive adhesive layer precursor thus formed is irradiated with ultraviolet rays to form a pressure-sensitive adhesive layer 2. As the condition of ultraviolet irradiation, the cumulative radiation is preferably within a range from 30 to 10,000 mJ/cm², and more preferably from 100 to 500 mJ/cm². When irradiation with ultraviolet rays is conducted at less than 30 mJ/cm², there is a case that curing of the pressure-sensitive adhesive layer becomes insufficient. As a result, the adhesion with the die bond film increases, and this causes a deterioration of the pickup property. Further, adhesive residue is generated in the die bond film after picking up. In contrast, when the irradiation of the ultraviolet rays exceeds 1,000 mJ/cm², there is a case that the base material is thermally damaged. Further, the tensile elastic modulus becomes too high by excessive curing of the pressure-sensitive adhesive layer and deterioration of the expansion property. The adhesive power becomes too low, and thus there is a case that chip fly occurs upon dicing the semiconductor wafer.

Next, the material for forming a die bond film 3 is coated on a sheet of release paper in a predetermined thickness, followed by drying under a prescribed condition to form the die bond film 3. A dicing die bond film is formed by transferring the die bond film 3 on the pressure-sensitive adhesive layer 2. Thus, a dicing die bond film 10 according to the present invention can be obtained.

### Method of Manufacturing Semiconductor Devise

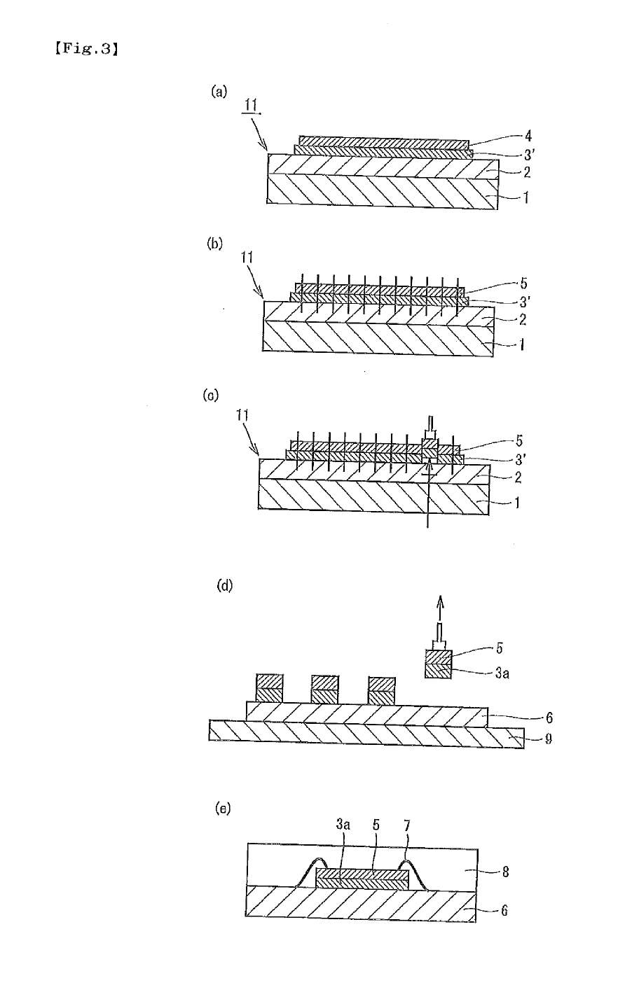

The method of manufacturing a semiconductor device using the dicing die bond film 11 of the present invention will be described below with reference to FIG. 3.

First, a semiconductor wafer 4 is pressure-bonded onto the die bond film 3′ of the dicing die bond film 11, and at the same time a dicing ring 12 (refer to FIG. 2) is pasted to the portion 2c (refer to FIG. 2) of the pressure-sensitive adhesive layer 2 where the dicing ring is pasted. The pressure-sensitive adhesive layer 2 contains the above-described polymer and the above-described crosslinking agent having a content of 0.5 to 2 parts by weight and is cured by irradiation with an ultraviolet ray under a prescribed condition. The 180 degree peeling adhesive power to a silicon mirror wafer of the portion 2c of the pressure-sensitive adhesive layer 2 where a dicing ring is pasted is in the above-described range, and the tensile storage modulus at 23° C. of the portion 2c where the dicing ring is pasted is in the above-described range. As a result, the adhesive power can be kept high on the portion 2c of the pressure-sensitive adhesive layer 2, and the dicing die bond film 11 can be suppressed from peeling from the dicing ring when dicing a semiconductor wafer as described later. This step is performed while applying pressure by a pressing means such as a pressure roll.

Next, dicing of the semiconductor wafer 4 is conducted. With this operation, a semiconductor chip 5 is formed by cutting the semiconductor wafer 4 into a prescribed size to make it into individual pieces. The dicing is conducted following an ordinary method from the circuit face side of the semiconductor wafer 4. Further, a cutting method, so-called full cut, in which cutting-in is conducted to the die bond film 3, can be adopted in the present step. Since the die bond film 3 is formed from an epoxy resin, even if the film is cut by dicing, it is possible to prevent the adhesive residue of the adhesive from generating on the cut surface, thus making it possible to prevent cut surfaces from reattaching to each other (blocking) and to achieve more satisfactory pickup of the semiconductor chip. The dicing apparatus that is used in the present step is not especially limited, and a conventionally known apparatus can be used. Further, since the semiconductor wafer 4 is adhered and fixed by the dicing die bond film 3, chipping and chip fly can be suppressed, and at the same time, damage of the semiconductor wafer 4 can be suppressed. Even when cutting-in is conducted to the pressure-sensitive adhesive layer 2 by dicing, the generation of scraps can be prevented because the pressure-sensitive adhesive layer 2 is cured by the ultraviolet ray irradiation.

Next, expansion of the dicing die bond film 11 is conducted. The expansion is conducted using a conventionally known expanding apparatus. The expanding apparatus has a donut-shaped outer ring that can push the dicing die bond film 11 downwards through the dicing ring and an inner ring having a smaller diameter than the outer ring and supporting the dicing die bond film 11. Since only the portion 2a in the pressure-sensitive adhesive layer 2 is cured by ultraviolet irradiation and the other portion 2b is not cured in the dicing die bond film 11, the space between the adjacent semiconductor chips can be sufficiently broadened without breaking. As a result, damage to the semiconductor chip by the semiconductor chips contacting to each other upon picking up, which is described later, can be prevented.

Picking up of the semiconductor chip 5 is performed to peel off the semiconductor chip 5 that is adhered and fixed to the dicing die bond film 11. Picking up is performed without irradiating the pressure-adhesive layer 2 with ultraviolet rays. The method of picking up is not especially limited, and various conventionally known methods can be adopted. Examples thereof include a method of pushing up the individual semiconductor chip 5 from the dicing die bond film 11 side using a needle and picking up the semiconductor chip 5 that is pushed up with a picking up apparatus. Since the peeling property of the pressure-sensitive adhesive layer 2 and the die bond film 3 is satisfactory in the dicing die bond film 11, the pickup can be performed by reducing the number of needles and by increasing the yield ratio even when the pushing up amount is small.

The semiconductor chip 5 picked up is adhered and fixed to an adherend 6 through the die bond film 3a interposed therebetween (die bonding). The adherend 6 is mounted onto a heat block 9. Examples of the adherend 6 include such as a lead frame, a TAB film, a substrate, and a semiconductor chip separately produced. The adherend 6 may be a deformable adherend that are easily deformed, or may be a non-deformable adherend (a semiconductor wafer, etc.) that is difficult to deform, for example.

A conventionally known substrate can be used as the substrate. Further, a metal lead frame such as a Cu lead frame and a 42 Alloy lead frame and an organic substrate composed of glass epoxy, BT (bismaleimide-triazine), and polyimide can be used as the lead frame. However, the present invention is not limited to this, and includes a circuit substrate that can be used by mounting a semiconductor element and electrically connecting with the semiconductor element.

When the die bond film 3 is a thermosetting type die bond film, the semiconductor chip 5 is adhered and fixed onto the adherend 6 by heat-curing to improve the heat resistance strength. Here, a product in which the semiconductor chip 5 is adhered and fixed onto a substrate etc. through the die bond film 3a interposed therebetween can be subjected to a reflow step. After that, wire bonding is performed by electrically connecting the tip of a terminal part (inner lead) of the substrate and an electrode pad (not shown) on the semiconductor chip 5 with a bonding wire 7, and furthermore, the semiconductor chip is sealed with a sealing resin 8, and the sealing resin 8 is after cured. Accordingly, the semiconductor device according to the present embodiment is manufactured.

### EXAMPLES

The preferred examples of this invention are illustratively described in detail hereinbelow. However, the materials, the compounding amount, etc. described in these examples are not intended to limit the scope of this invention to these only unless otherwise stated, and they are only explanatory examples. Further, part in each example is a weight standard unless otherwise stated.

### Example 1

### Manufacture of Dicing Film

To a reaction vessel equipped with a condenser, a nitrogen introducing tube, a thermometer and a stirrer, 86.4 parts of 2-ethylhexyl acrylate (hereinafter referred to as “2EHA”), 13.6 parts of 2-hydroxyethyl acrylate (hereinafter referred to as “HEA”), 0.2 part of benzoyl peroxide and 65 parts of toluene were charged and then polymerized in a nitrogen gas flow at 61° C. for 6 hours to obtain an acrylic polymer A.

To this acrylic polymer A, 14.6 parts of 2-methacryloyloxyethyl isocyanate (hereinafter referred to as “MOI”) was added and the mixture was subjected to an addition reaction treatment in an air flow at 50° C. for 48 hours to obtain an acrylic polymer A′.

A pressure-sensitive adhesive composition solution A was obtained by adding 0.5 parts of a polyisocyanate compound (trade name: Colonate L manufactured by Nippon Polyurethane Industry Co., Ltd.) and 5 parts of a photopolymerization initiator (trade name: Irgacure 651 manufactured by Ciba Specialty Chemicals Inc.) to 100 parts of the acrylic polymer A′.

A pressure-sensitive adhesive layer having a thickness of 10 μm was formed by applying the pressure-sensitive adhesive composition solution A onto the surface of a PET peeling liner subjected to a silicone treatment and by drying with heat at 120° C. for 2 minutes. Then, a polyolefin film was pasted onto the formed pressure-sensitive adhesive layer. A dicing film A was produced by performing a crosslinking treatment by heating at 50° C. for 24 hours and irradiating a region that is larger than the portion where the wafer is pasted and that is closer to the center than the portion where the dicing ring is pasted with an ultraviolet ray from the polyolefin film side using an ultraviolet ray irradiation apparatus (trade name: UM-810) manufactured by Nitto Seiki Co., Ltd.) so that the irradiance was 20 mW/cm² and the accumulative light amount was 400 mJ/cm².

### <Production of Die Bond Film>

20 parts of an epoxy resin (a) (Epicoat 1001 manufactured by Japan Epoxy Resin Co., Ltd.), 22 parts of a phenol resin (b) (MEH 7851 manufactured by Mitsui Chemicals, Inc.), 100 parts of an acrylic ester polymer (c) containing ethyl acrylate-methyl methacrylate as a main component (Paracron W-197CM manufactured by Negami Chemical Industries Co., Ltd.), and 180 parts of spherical silica as a filler (d) (SO-25R manufactured by Admatechs Co., Ltd.) were dissolved in methylethylketone, and the concentration was adjusted to be 23.6% by weight. A die bond film A having a thickness of 40 μm was produced by applying this adhesive composition solution onto the surface of a PET peeling liner subjected to a silicone treatment and drying the solution at 130° C. for 2 minutes.

### <Production of Dicing Die Bond Film>

A dicing die bond film A was produced by peeling the peeling liner from the dicing film A and pasting the die bond film layer of the die bond film A to the portion that is irradiated with an ultraviolet ray at 40±3° C.

### Example 2

### Production of Dicing Film

A dicing film B was obtained in the same manner as in Example 1 except the added amount of the polyisocyanate compound was changed to 1 part.

### <Production of Dicing Die Bond Film>

A dicing die bond film B was produced by peeling the peeling liner from the dicing film B and by pasting the die bond film layer of the die bond film A to the portion that was irradiated with an ultraviolet ray at 40±3° C.

### Example 3

### Production of Dicing Film

A dicing film C was obtained in the same manner as in Example 1 except the added amount of the polyisocyanate compound was changed to 2 parts.

### <Production of Dicing Die Bond Film>

A dicing die bond film C was produced by peeling the peeling liner from the dicing film C and by pasting the die bond film layer of the die bond film A to the portion that was irradiated with an ultraviolet ray at 40±3° C.

### Example 4

### Production of Dicing Film

A dicing film D was produced in the same manner as in Example 1 except the added amount of the polyisocyanate compound was changed to 2 parts and 30 parts of an ultraviolet-ray curing-type oligomer (trade name: Shiko UV-1700B manufactured by Nippon Synthetic Chemical Industry Co., Ltd.) was added.

### <Production of Dicing Die Bond Film>

A dicing die bond film D was produced by peeling the peeling liner from the dicing film D and by pasting the die bond film layer of the die bond film A to the portion that was irradiated with an ultraviolet ray at 40±3° C.

### Comparative Example 1

### Production of Dicing Film

A dicing film E was obtained in the same manner as in Example 1 except the added amount of the polyisocyanate compound was changed to 0.3 parts.

### <Production of Dicing Die Bond Film>

A dicing die bond film E was produced by peeling the peeling liner from the dicing film E and by pasting the die bond film layer of the die bond film A to the portion that was irradiated with an ultraviolet ray at 40±3° C.

### Comparative Example 2

### Production of Dicing Film

A dicing film F was obtained in the same manner as in Example 1 except the added amount of the polyisocyanate compound was changed to 3 parts.

### <Production of Dicing Die Bond Film>

A dicing die bond film F was produced by peeling the peeling liner from the dicing film F and by pasting the die bond film layer of the die bond film A to the portion that was irradiated with an ultraviolet ray at 40±3° C.

### (180 Degree Peeling Adhesive Power to a Silicon Mirror Wafer of Portion Pasted to Dicing Ring)

A silicon mirror wafer was wiped with a cloth containing toluene, with a cloth containing methanol, and then with a cloth containing toluene. The portion of the dicing film that is pasted to the dicing ring and that had not been irradiated with an ultraviolet ray was cut into a rectangular piece having 20 mm of a tape width, a peeling liner was peeled, and the resultant was pasted to the silicon mirror wafer. After that, the resultant was kept still under a room temperature atmosphere for 30 minutes.

After the resultant was kept still for 30 minutes, the adhesive power was measured under peeling conditions of an angle θ between the surface of the pressure-sensitive adhesive layer and the surface of the silicon mirror wafer of 180°, a pulling speed of 300 mm/min, and room temperature (23° C.). The result is shown in Table 1.

### (Tensile Storage Modulus of Pressure-Sensitive Adhesive)

A pressure-sensitive adhesive layer sandwiched by PET peeling liners was produced by pasting PET peeling liners instead of the polyolefin film in the process of obtaining the dicing films A to F. A pressure-sensitive adhesive layer cured by an ultraviolet ray was produced by irradiating the pressure-sensitive adhesive layer with an ultraviolet ray under the same conditions as in producing the dicing film. After that, a stick-shaped sample 100 mm in length was produced by cutting the cured pressure-sensitive adhesive layer into a rectangular piece 50 mm wide and 100 mm long, peeling one of the PET peeling liners, and rolling only the pressure-sensitive adhesive layer into a stick. This sample was pulled under conditions of a distance between chucks of 50 mm, a peeling speed of 50 mm/min, and room temperature (23° C.), and the tensile storage modulus (Young's modulus) was obtained from the slope of the pulling length and stress. The result is shown in Table 1.

### (Dicing Property)

A silicon wafer ground to a thickness of 75 μm was pasted to the dicing die bond film at 40° C., and dicing was performed under the following conditions so that the film had a size of 10 mm×10 mm. The dicing property was evaluated as ◯ when chip fly did not occur, and x when chip fly occurred. The result is shown in Table 1.

### <Dicing Conditions>

Dicing apparatus: DISCO DFD6361 manufactured by DISCO Corporation

Dicing ring: 2-8-1 manufactured by DISCO Corporation

Dicing speed: 80 mm/sec

Dicing Blade:
Z1; 2050HEDD manufactured by DISCO Corporation
Z2; 2050HEBB manufactured by DISCO Corporation

Dicing Blade Rotation Speed:
Z1; 40,000 rpm
Z2; 40,000 rpm

Blade Height:
Z1; 0.155 mm
Z2; 0.085 mm

Cutting method: A mode/step cut

Chip size: 10.0 mm square

### (Pickup Property)

The diced sample was picked up under the following conditions.

### <Pickup Conditions>

Die bonder apparatus: SPA-300 manufactured by Shinkawa Ltd.

Mounting frame: 2-8-1 manufactured by DISCO Corporation

Wafer type: Mirror wafer (no pattern)

Chip size: 10 mm×10 mm

Chip thickness: 75 μm

Number of needles: 9 needles

Needle pushing speed: 5 mm/sec

Collet maintaining time: 1000 msec

Expand: pulling down distance 3 mm

Needle pushing distance: 300 μm

The evaluation was performed by picking up 10 chips, and evaluating the case as ◯ when all of the chips were picked up, Δ when 1 to 9 chips were picked up, and x when none of the chips were picked up. The result is shown in Table 1.

### (Wafer Mounting Evaluation)

Wafer mounting was performed under the following conditions, and evaluation was performed 48 hours after pasting by evaluating the case as x when the wafer was peeled from the dicing ring and ◯ when the wafer was not peeled from the dicing ring. The wafer was evaluated as x also when only the outer circumference of the dicing film was peeled. The result is shown in Table 1.

### <Wafer Mounting Conditions>

Wafer mounting apparatus: MSA-840 manufactured by Nitto Seiki Co., Ltd.

Dicing ring: 2-8-1 manufactured by DISCO Corporation

Wafer type: mirror wafer having a thickness of 760 μm and a diameter of 8 inches

Lamination temperature: 55° C.

Lamination pressure: 2 kgf

Lamination speed: 10 mm/sec

Chuck table height: 4 mm

### (Adhesive Residue to Dicing Ring)

The dicing die bond film pasted to the dicing ring was peeled by hand, and the case was evaluated by visual observation as ◯ when no paste remained on the dicing ring, and x when the paste remained. The result is shown in Table 1.

TABLE 1

| | 180 DEGREE PEELING | TENSILE STORAGE | | | | |
|---|---|---|---|---|---|---|
| | ADHESIVE POWER (N/ | MODULUS (MPa) OF | | | | ADHESIVE |
| | 20 mm) TO SILICON | PRESSURE-SENSITIVE | DICING | PICKUP | WAFER MOUNTING | RESIDUE TO THE |
| | MIRROR WAFER | ADHESIVE | PROPERTY | PROPERTY | PROPERTY | DICING RING |
| Example 1 | 2.2 | 0.09 | ∘ | ∘ | ∘ | ∘ |
| Example 2 | 1.4 | 0.19 | ∘ | ∘ | ∘ | ∘ |
| Example 3 | 1.2 | 0.27 | ∘ | ∘ | ∘ | ∘ |
| Example 4 | 1.8 | 0.22 | ∘ | ∘ | ∘ | ∘ |
| Comparative | 3.6 | 0.02 | ∘ | ∘ | ∘ | x |
| Example 1 | | | | | | |
| Comparative | 0.8 | 0.63 | ∘ | ∘ | x | ∘ |
| Example 2 | | | | | | |

1. A dicing die bond film comprising a dicing film including a base and a pressure-sensitive adhesive layer provided thereon, and a die bond film provided on the dicing film, wherein
the pressure-sensitive adhesive layer contains a polymer formed by performing an addition reaction on an acrylic polymer containing 10 to 40 mol % of a hydroxyl group-containing monomer with an isocyanate compound having 70 to 90 mol % of a radical reactive carbon-carbon double bond with respect to the hydroxyl group-containing monomer, and a crosslinking agent having two or more functional groups exhibiting reactivity to a hydroxyl group in a molecule and having a content of 0.5 to 2 parts by weight to 100 parts by weight of the polymer, and is cured by ultraviolet ray radiation under a prescribed condition,
the 180 degree peeling adhesive power to a silicon mirror wafer of a portion of the pressure-sensitive adhesive layer where a dicing ring is pasted is 1.0 N/20 mm tape width or more and 10.0 N/20 mm tape width or less under conditions of a measurement temperature of 23±3° C. and a tensile speed of 300 mm/min,
the tensile storage modulus at 23° C. of a portion where the dicing ring is pasted is 0.05 MPa or more and less than 0.4 MPa, and
the die bond film is pasted to the pressure-sensitive adhesive layer after irradiation with an ultraviolet ray.

2. The dicing die bond film according to claim 1, wherein the pressure-sensitive adhesive layer further comprises 5 to 100 parts by weight of an ultraviolet-ray curing-type oligomer component to 100 parts by weight of the polymer.

3. The dicing die bond film according to claim 1, wherein the irradiation with an ultraviolet ray is performed in a range of 30 to 1000 mJ/cm².

4. The dicing die bond film according to claim 1, wherein the hydroxyl group-containing monomer is at least one kind selected from the group consisting of 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl)methyl(meth)acrylate.

5. The dicing die bond film according to claim 1, wherein the isocyanate compound having a radical reactive carbon-carbon double bond is at least any of 2-methacryloyloxyethyl isocyanate and 2-acryloyloxyethyl isocyanate.

6. The dicing die bond film according to claim 1, wherein the pressure-sensitive adhesive layer does not contain acrylic acid.

7. A method of manufacturing a dicing die bond film comprising a dicing film including a base and a pressure-sensitive adhesive layer provided thereon, and a die bond film provided on the pressure-sensitive adhesive layer, comprising the steps of:
forming on the base a pressure-sensitive adhesive layer precursor that is constituted with a polymer formed by performing an addition reaction on an acrylic polymer containing 10 to 40 mol % of a hydroxyl group-containing monomer with an isocyanate compound having 70 to 90 mol % of a radical reactive carbon-carbon double bond with respect to the hydroxyl group-containing monomer, and a crosslinking agent having two or more functional groups exhibiting reactivity to a hydroxyl group in a molecule and having a content of 0.5 to 2 parts by weight to 100 parts by weight of the polymer,
forming a pressure-sensitive adhesive layer in which the 180 degree peeling adhesive power to a silicon mirror wafer of a portion of the pressure-sensitive adhesive layer where a dicing ring is pasted is 1.0 N/20 mm tape width or more and 10.0 N/20 mm tape width or less under conditions of a measurement temperature of 23±3° C. and a tensile speed of 300 mm and in which the tensile storage modulus at 23° C. of a portion where the dicing ring is pasted is 0.05 MPa or more and less than 0.4 MPa by irradiating the pressure-sensitive adhesive layer precursor with an ultraviolet ray under a prescribed condition, and
pasting the die bond film onto the pressure-sensitive adhesive layer.

8. The method of manufacturing a dicing die bond film according to claim 7, wherein the pressure-sensitive adhesive layer precursor contains 0 to 100 parts by weight of an ultraviolet-ray curing-type oligomer component to 100 parts by weight of the polymer.

9. The method of manufacturing a dicing die bond film according to claim 7, wherein the irradiation with an ultraviolet ray is performed in a range of 30 to 1000 mJ/cm².

10. A method of manufacturing a semiconductor device using a dicing die bond film comprising a dicing film including a base and a pressure-sensitive adhesive layer provided thereon and a die bond film provided on the pressure-sensitive adhesive layer, comprising the steps of:
preparing the dicing die bond film according to claim 1 and pasting the dicing ring to the portion of the pressure-sensitive adhesive layer where the dicing ring is pasted,
pressure-bonding a semiconductor wafer onto the die bond film,
forming a semiconductor chip by dicing the semiconductor wafer together with the die bond film, and
peeling the semiconductor chip from the pressure-sensitive adhesive layer together with the die bond film, and wherein
the step of pressure-bonding the semiconductor wafer to the step of peeling the semiconductor chip are performed without irradiating the pressure-sensitive adhesive layer with an ultraviolet ray.

11. A method of manufacturing a semiconductor device using a dicing die bond film comprising a dicing film including a base and a pressure-sensitive adhesive layer provided thereon and a die bond film provided on the pressure-sensitive adhesive layer, comprising:
pressure-bonding a semiconductor wafer to the dicing die bond film according to claim 1,
forming a semiconductor chip by dicing the semiconductor wafer together with the die bond film that has been pressure-bonded thereto, and
peeling the semiconductor chip from the pressure-sensitive adhesive layer together with the die bond film,
wherein from the pressure-bonding of the semiconductor wafer to the peeling the semiconductor chip, no intervening step of irradiating the pressure-sensitive adhesive layer with an ultraviolet ray is performed.
